(19) United States
(12) Patent Application Publication
(10) Pub. No.: US 2026/0013384 A1
(43) Pub. Date: Jan. 8, 2026

(54) DISPLAY MODULE, MANUFACTURING METHOD THEREFOR, AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Shaopeng LI, Beijing (CN); Wenze LI, Beijing (CN); Hao DENG, Beijing (CN); Weiben ZHANG, Beijing (CN); Rongkun FAN, Beijing (CN)

(21) Appl. No.: 18/992,180

(22) PCT Filed: May 29, 2024
(86) PCT No.: PCT/CN2024/096077

§ 371 Date: Jan. 7, 2025

(30) Foreign Application Priority Data
May 30, 2023 (CN) 202310632197.X

(51) Int. Cl. H10K 59/80; H05K 7/20; H10K 59/12; H10K 59/95; H10K 102/00

(52) U.S. Cl. CPC H10K 59/8794; H05K 7/20963; H10K 59/1201; H10K 59/95; H10K 2102/311

(57) ABSTRACT

Provided is a display module. In the display module, a flexible printed circuit board is disposed on a side, away from a display region, of a non-display region of a display panel, and has a groove region exposing the non-display region. A driver chip is disposed within the groove region of the flexible printed circuit board and spaced apart from the flexible printed circuit board. A thermally conductive structure is disposed within a gap between the driver chip and the flexible printed circuit board and is in contact with both the driver chip and the flexible printed circuit board.

### CROSS-REFERENCE TO RELATED APPLICATIONS

This application is a U.S. national stage of international application No. PCT/CN2024/096077, filed on May 29, 2024, which claims priority to Chinese Patent Application No. 202310632197.X, filed on May 30, 2023, and entitled “DISPLAY MODULE, PREPARATION METHOD THEREOF AND DISPLAY DEVICE,” the disclosures of which are herein incorporated by reference in their entireties.

### TECHNICAL FIELD

The present disclosure relates to the field of display technologies, and in particular, to a display module, a manufacturing method therefor, and a display device.

### BACKGROUND

With the development of display technologies, a foldable display module that can be easily carried by a user has emerged.

### SUMMARY

The present disclosure provides a display module, a manufacturing method therefor, and a display device. The technical solutions are as follows.

According to an aspect, a display module is provided. The display module includes:
a display panel, including a display region, a bending region, and a non-display region that are sequentially connected, wherein the non-display region is bent to a side, away from a light-exiting surface of the display panel, of the display region through the bending region;
a flexible printed circuit board, disposed on a side, away from the display region, of the non-display region and having, in a first direction, a groove region exposing the non-display region;
a driver chip, disposed on the side, away from the display region, of the non-display region and within the groove region of the flexible printed circuit board and spaced apart from the flexible printed circuit board in a second direction, the second direction being intersected with the first direction; and
a thermally conductive structure, disposed within a gap between the driver chip and the flexible printed circuit board and being in contact with both the driver chip and the flexible printed circuit board.

In some embodiments, the thermally conductive structure includes a thermally conductive adhesive.

In some embodiments, an orthographic projection of the thermally conductive structure on the display panel covers an orthographic projection of the driver chip on the display panel.

In some embodiments, the non-display region includes: a first bonding region and a second bonding region spaced apart from each other in the second direction, the first bonding region being away from the bending region relative to the second bonding region;
wherein the flexible printed circuit board is bonded to the display panel at the first bonding region and the second bonding region is exposed by the grove region of the flexible printed circuit board; and
the driver chip is disposed on a side, away from the display region, of the second bonding region and is bonded to the display panel at the second bonding region.

In some embodiments, the thermally conductive structure is further disposed between the flexible printed circuit board and the non-display region.

In some embodiments, a cross-section of the thermally conductive structure in the first direction has a curved edge.

In some embodiments, the display module further includes:
a first back film, a bracket layer, and a second back film that are disposed between the display region and the non-display region and sequentially stacked along the first direction;
wherein at least one first groove is defined in the bracket layer, an orthographic projection of the at least one first groove on the display panel being overlapped with an orthographic projection of the thermally conductive structure on the display panel.

In some embodiments, the display module further includes:
a first adhesive layer, disposed between the first back film and the bracket layer and configured to adhere the first back film to the bracket layer; and
a second adhesive layer, disposed between the second back film and the bracket layer and configured to adhere the second back film to the bracket layer;
wherein a material of the first adhesive layer includes a flexible material and a material of the second adhesive layer includes a non-flexible material; and
at least one second groove is defined in the second adhesive layer, an orthographic projection of the at least one second groove on the display panel being overlapped with the orthographic projection of the thermally conductive structure on the display panel.

In some embodiments, the display module further includes:
a thermally conductive reinforcement layer, disposed between the bracket layer and at least one of the first back film and the second back film.

In some embodiments, the thermally conductive reinforcement layer is disposed between the bracket layer and the second back film and adhered to the bracket layer via the second adhesive layer; and
at least one third groove is defined in the thermally conductive reinforcement layer, an orthographic projection of the at least one third groove on the display panel being overlapped with the orthographic projection of the thermally conductive structure on the display panel.

In some embodiments, a plurality of first grooves spaced apart from each other along the second direction are defined in the bracket layer, the plurality of first grooves being disposed on a side, close to the flexible printed circuit board in the first direction, of the bracket layer, and orthographic projections of the plurality of first grooves on the display panel being overlapped with the orthographic projection of the thermally conductive structure on the display panel; and/or,
one second groove is defined in the second adhesive layer, the one second groove running through the second adhesive layer in the first direction, and an orthographic projection of the one second groove on the display panel being within the orthographic projection of the thermally conductive structure on the display panel;
and/or,
a plurality of third grooves spaced apart from each other along the second direction are defined in the thermally conductive reinforcement layer, the plurality of third grooves being disposed at a middle position of the thermally conductive reinforcement layer in the first direction, and the orthographic projections of the plurality of third grooves on the display panel being overlapped with the orthographic projection of the thermally conductive structure on the display panel.

In some embodiments, a plurality of first grooves are defined in the bracket layer, and a plurality of third grooves are defined in the thermally conductive reinforcement layer; wherein the plurality of first grooves and the plurality of third grooves are arranged in any of the following patterns:
the plurality of first grooves and the plurality of third grooves are all sequentially arranged along the second direction and a third direction, and in any direction of the second direction and the third direction, orthographic projections of the plurality of first grooves on the display panel and orthographic projections of the plurality of third grooves on the display panel are staggered;
the plurality of first grooves and the plurality of third grooves are all sequentially arranged along the second direction and the third direction, the plurality of first grooves are in one-to-one correspondence with the plurality of third grooves, and the orthographic projection of each of the plurality of first grooves on the display panel is overlapped with the orthographic projection of each of the plurality of third grooves on the display panel; or
the plurality of first grooves are sequentially arranged along the third direction, the plurality of third grooves are sequentially arranged along the second direction, and the orthographic projection of each of the plurality of first grooves on the display panel is overlapped with the orthographic projection of each of the plurality of third grooves on the display panel;
wherein the third direction and the second direction are intersected in a same plane, and the third direction and the second direction are intersected with the first direction respectively in different planes.

In some embodiments, the orthographic projection of any one of the first groove, the second groove, and the third groove on the display panel has a shape of a hexagon or rectangle.

In some embodiments, the material of the first adhesive layer includes polyimide; a material of the bracket layer includes stainless steel or metallic copper; the material of the second adhesive layer includes polyethylene terephthalate; and a material of the thermally conductive reinforcement layer includes metallic copper.

In some embodiments, the flexible printed circuit board includes:
a plurality of protective layers and a plurality of metal trace layers that are alternately stacked along the first direction, wherein a material of the metal trace layer includes metallic copper.

In some embodiments, the display module further includes:
a connection portion, disposed between the flexible printed circuit board and the non-display region and configured to connect the flexible printed circuit board to the display panel.

In some embodiments, the display module further includes:
a double-sided adhesive, overlaid on a surface, away from the display region and the non-display region, of the bending region and configured to protect the bending region.

According to another aspect, a method for manufacturing a display module is provided. The method is applicable to manufacturing the display module as described in the above aspect. The method includes:
providing a display panel, wherein the display panel includes a display region, a bending region, and a non-display region that are sequentially connected, the non-display region being bent to a side, away from a light-exiting surface of the display panel, of the display region through the bending region;
forming a flexible printed circuit board on a side, away from the display region, of the non-display region, wherein the formed flexible printed circuit board has, in a first direction, a groove region exposing the non-display region;
forming a driver chip in the groove region of the flexible printed circuit board, wherein the formed driver chip and the flexible printed circuit board are spaced apart from each other in a second direction, the second direction being intersected with the first direction; and
forming a thermally conductive structure in a gap between the driver chip and the flexible printed circuit board, wherein the formed thermally conductive structure is in contact with both the driver chip and the flexible printed circuit board.

According to another aspect, a display module is provided. The display module includes:
a display panel, including a display region, a bending region, and a non-display region that are sequentially connected, wherein the non-display region is bent to a side, away from a light-exiting surface of the display panel, of the display region through the bending region;
a flexible printed circuit board, disposed on a side, away from the display region, of the non-display region, bonded to the non-display region, and having, in a first direction, a groove region exposing the non-display region;
a driver chip, disposed within the groove region of the flexible printed circuit board and bonded to the non-display region, wherein in a second direction, any side wall of the driver chip is spaced apart from any side wall of the flexible printed circuit board, the second direction being intersected with the first direction; and
a thermally conductive structure, disposed within a gap between the driver chip and the flexible printed circuit board and being in contact with each of the driver chip, the flexible printed circuit board, and the non-display region.

According to another aspect, a display device is provided. The display device includes: a power supply assembly, and a display module as described in the above aspects;
wherein the power supply assembly is coupled to the display module and configured to supply power to the display module.

### BRIEF DESCRIPTION OF DRAWINGS

In order to describe the technical solutions in the embodiments of the present disclosure more clearly, the following briefly introduces the accompanying drawings required for describing the embodiments. Apparently, the accompanying drawings in the following description show merely some embodiments of the present disclosure, and a person skilled in the art can still derive other drawings from these accompanying drawings without creative efforts.

FIG. 1 is a schematic diagram of a film layer structure of a display module according to some embodiments of the present disclosure;

FIG. 2 is a schematic diagram of an unfolded plane of a display panel in a display module according to some embodiments of the present disclosure;

FIG. 3 is a structural schematic diagram of some film layers of a display module according to some embodiments of the present disclosure;

FIG. 4 is another structural schematic diagram of some film layers of a display module according to some embodiments of the present disclosure;

FIG. 5 is yet another structural schematic diagram of some film layers of a display module according to some embodiments of the present disclosure;

FIG. 6 is another structural schematic diagram of film layers of a display module according to some embodiments of the present disclosure;

FIG. 7 is still another structural schematic diagram of some film layers of a display module according to some embodiments of the present disclosure;

FIG. 8 is a schematic diagram of groove arrangement in a display module according to some embodiments of the present disclosure;

FIG. 9 is another schematic diagram of groove arrangement in a display module according to some embodiments of the present disclosure;

FIG. 10 is yet another schematic diagram of groove arrangement in a display module according to some embodiments of the present disclosure;

FIG. 11 is a flowchart of a method for manufacturing a display module according to some embodiments of the present disclosure;

FIG. 12 is a flowchart of a manufacturing process of a display module according to some embodiments of the present disclosure; and

FIG. 13 is a structural schematic diagram of a display device according to some embodiments of the present disclosure.

### DETAILED DESCRIPTION

To make the objectives, technical solutions, and advantages of the present disclosure clearer, the embodiments of the present disclosure are further described hereinafter with reference to the accompanying drawings.

In related arts, a foldable display module generally includes a display panel including a display region, a bending region, and a non-display region, a plurality of pixels disposed in the display region, and a flexible printed circuit board and a driver chip disposed in the non-display region. The non-display region is bent to a side, away from a light-exiting surface of the display panel, of the display region through the bending region. The flexible printed circuit board and the driver chip work together to light up the plurality of pixels, so as to drive the display panel to display a picture. Further, the driver chip is generally encased by the flexible printed circuit board.

Due to the increasing demand for refresh rate, a driver chip of a conventional display module is easily hot upon working for a long time, which leads to abnormal brightness of pixels at positions corresponding to the driver chip, resulting in a display abnormality problem similar to yellowing. Based on this, embodiments of the present disclosure provide a display module that can solve the display abnormality problem caused by the heating problem.

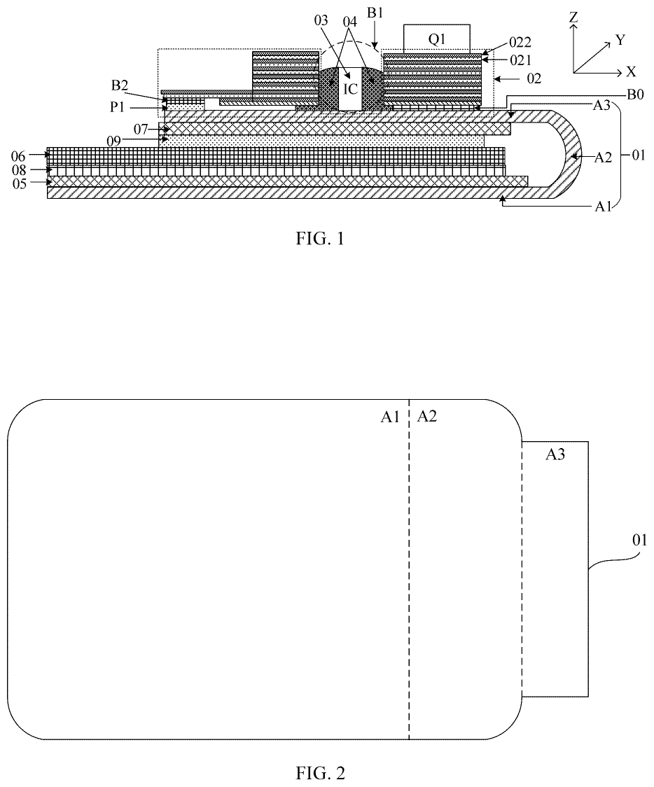

FIG. 1 is a structural schematic diagram of a display module according to some embodiments of the present disclosure. As shown in FIG. 1, the display module includes: a display panel 01, a flexible printed circuit board (FPC) 02, a driver chip 03, and a thermally conductive structure 04.

On the basis of FIG. 1, FIG. 2 is a planar schematic diagram of the display panel 01 in an unfolded state. As can be seen from FIGS. 1 and 2, the display panel 01 includes a display region A1, a bending region A2, and a non-display region A3 that are sequentially connected, wherein the non-display region A3 is bent to a side, away from a light-exiting surface of the display panel 01, of the display region A1 through the bending region A2. It is to be noted that in the embodiments of the present disclosure, the display region A1, the bending region A2, and the non-display region A3 of the display panel 01 are different portions of a same substrate of the display panel 01. Accordingly, in some embodiments, the display region A1 is capable of bending like the bending region A2. The form shown in FIG. 1 is only an example in which the display region A1 is not bent.

The light-exiting surface of the display panel 01 refers to a surface for displaying a picture, and accordingly, a surface, away from the light-exiting surface, of the display panel 01 is referred to as a back surface of the display panel 01. In other words, in some embodiments, the side of the display region A1 is the light-exiting surface for displaying a picture, the side of the non-display region A3 is the back surface that does not display a picture, and the bending region A2 is partially or wholly configured to display a picture, or does not display a picture. This type of display module is usually applicable to foldable display products, such as foldable cell phones.

In some embodiments, the display panel 01 described in the present disclosure is an organic light-emitting diode (OLED) display panel. In some embodiments, the display panel 01 further includes a plurality of pixels. Each pixel includes a pixel circuit and a light-emitting element. The pixel circuit is coupled to the light-emitting element and is configured to drive the light-emitting element to emit light. For the OLED display panel, the light-emitting element is an OLED including an anode, a light-emitting layer, and a cathode that are stacked in sequence, wherein the light-emitting layer includes a light-emitting material for emitting light of a corresponding color.

Still referring to FIG. 1, it can also be seen that the flexible printed circuit board 02 is disposed on a side, away from the display region A1, of the non-display region A3, and the flexible printed circuit board 02 has, in a first direction Z shown in FIG. 1, a groove region (which is also referred to as an aperture region in some embodiments) B1 exposing the non-display region A3. That is, as shown in FIG. 1, in some embodiments, the flexible printed circuit board 02 is disposed on the back surface of the display panel 01, and is divided into two portions by the groove region B1, thereby exposing the non-display region A3.

Still referring to FIG. 1, it can be seen that the driver chip 03, i.e., an integrated circuit (IC) chip, is disposed on the side, away from the display region A1, of the non-display region A3, within the groove region B1 of the flexible printed circuit board 02, and spaced apart from the flexible printed circuit board 02 in the second direction X. That is, in the embodiments of the present disclosure, the driver chip 03 is disposed on the back surface of the display panel 01 like the flexible printed circuit board 02, and is disposed within the groove region B1 of the flexible printed circuit board 02 and spaced apart from the flexible printed circuit board 02.

In this way, the driver chip 03 is exposed in the groove region B1, and achieves heat exchange with the outside. The driver chip 03 is provided with a heat dissipation path, thereby achieving better heat dissipation, avoiding the heat problem of the driver chip 03 upon working for a long period of time, and thus avoiding the light-emitting material at the position corresponding to the driver chip 03 from being damaged by the influence of high temperature. In some embodiments, the driver chip 03 is electrically connected to the pixel circuit described in the above embodiments, and configured to drive the pixel circuit to control the light-emitting elements to emit light.

The second direction X intersects the first direction Z. In some embodiments, referring to FIG. 1, the first direction Z is perpendicular to the carrying surface of the display panel 01, and the second direction X is parallel to the carrying surface of the display panel 01. On the basis of the above, in some embodiments, the second direction X and the first direction Z are perpendicular to each other as shown in FIG. 1.

Still referring to FIG. 1, it can be seen that the thermally conductive structure 04 is disposed in a gap between the driver chip 03 and the flexible printed circuit board 02, and is in contact with both the driver chip 03 and the flexible printed circuit board 02. That is, in embodiments of the present disclosure, a thermally conductive structure 04 capable of conducting heat is provided in the gap between the driver chip 03 and the flexible printed circuit board 02, and the thermally conductive structure 04 at least encases a side wall of the driver chip 03 and is in contact with a hole wall of the groove region B1 of the flexible printed circuit board 02.

In this way, a better heat dissipation path is further provided for the driver chip 03, so that the heat of the driver chip 03 is exported by the thermally conductive structure 04 and uniformly dispersed to the flexible printed circuit board 02, and the heat is exchanged with the outside through the flexible printed circuit board 02. That is, better heat dissipation for the driver chip 03 is achieved, the serious heat problem of the driver chip 03 upon working for a long time is avoided, and thus the light-emitting material at the position corresponding to the driver chip 03 is avoided from being damaged by the influence of high temperature. By forming the groove region B1 and disposing the thermally conductive structure 04, the display abnormality problem similar to yellowing at the position corresponding to the driver chip 03 of the display panel 01 is effectively avoided.

In summary, the embodiments of the present disclosure provide a display module. In the display module, a flexible printed circuit board disposed in a non-display region, that is bent to a side, away from the light-exiting surface, of the display region through a bending region, has a groove region that exposes the non-display region. The driver chip is disposed in the groove region and is spaced apart from the flexible printed circuit board. In addition, the gap between the driver chip and the flexible printed circuit board is filled with a thermally conductive structure. In this way, better heat dissipation for the driver chip is achieved, and the problem of abnormal pixel brightness at the position corresponding to the driver chip caused by the heat of the driver chip upon working for a long time is avoided. That is, the display abnormality problem similar to yellowing of the display panel in the display module is avoided, i.e., a good display effect of the display panel is ensured.

In some embodiments, referring to FIG. 1, the flexible printed circuit board 02 as described in the embodiments of the present disclosure includes: a plurality of protective layers 021 and a plurality of metal trace layers 022 that are alternately stacked along a first direction Z (e.g., a direction away from the non-display region A3.)

That is, as shown in FIG. 1, each of the two portions of the flexible printed circuit board 02 divided by the groove region B1 includes multiple groups of the protective layer 021 and the metal trace layer 022 stacked in sequence. On the basis of the above structure, in some embodiments, the thermally conductive structure 04 is connected to the driver chip 03 and the metal trace layer 022 of the flexible printed circuit board 02 to at least enhance the dissipation of heat in the first direction Z and the second direction X, so that heat of the driver chip 03 is effectively conducted out by the metal trace layer 022 and evenly distributed onto the flexible printed circuit board 02, thereby achieving effective heat exchange with the outside, i.e., achieving reliable heat dissipation for the driver chip 03.

In some embodiments, the protective layer 021 is a solder resist ink, such as a green solder resist ink which is also known as a solder mask. In some embodiments, the material of the metal trace layer 022 includes: metallic copper Cu, and accordingly, the metal trace layer 022 is also referred to as a copper foil trace layer. Because the metallic copper Cu has a better heat dissipation ability, the heat conducted via the thermally conductive structure 04 is further reliably exported.

In some embodiments, the thermally conductive structure 04 as described in embodiments of the present disclosure includes a thermally conductive adhesive. That is, the thermally conductive adhesive fills in the gap between the driver chip 03 and the flexible printed circuit board 02 in the groove region B1, so as to export the heat of the driver chip 03. In addition, by providing the thermally conductive adhesive as the thermally conductive structure 04, the strength of the driver chip 03 is improved, and the process reliability of the display module is increased.

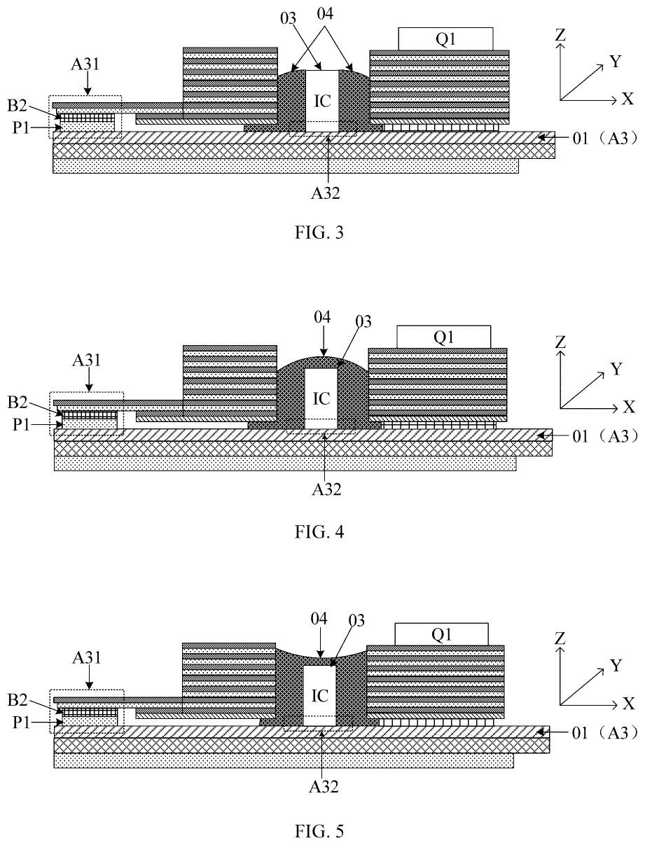

In some embodiments, as can be seen in conjunction with the schematic diagrams of some film layers shown in the above FIGS. 1 and 3, the thermally conductive structure 04 only encases the left and right side walls of the driver chip 03 within the groove region B1.

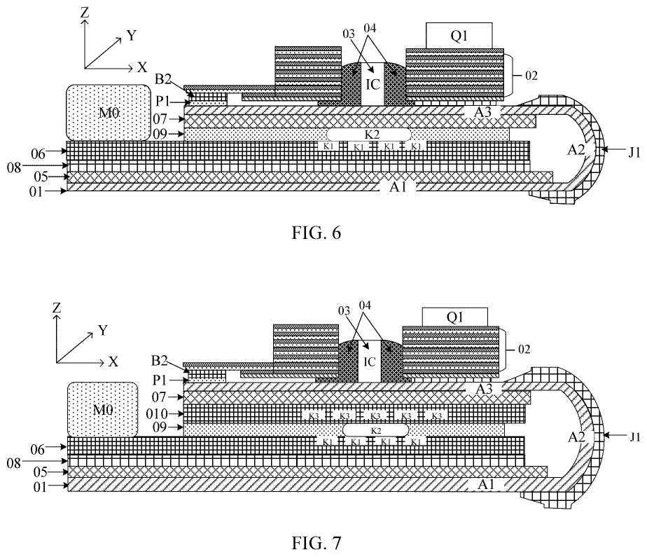

Alternatively, in other embodiments, respectively referring to the schematic diagrams of some film layers as shown in FIGS. 4 and 5, an orthographic projection of the thermally conductive structure 04 on the display panel 01 as documented in the embodiments of the present disclosure covers the orthographic projection of the driver chip 03 on the display panel 01. That is, the thermally conductive structure 04 not only encases the left and right side walls of the driver chip 03 within the groove region B1, but also encases the upper side (i.e., the side of the driver chip 03 that is away from the non-displayed region A3 among the upper and lower sides of the driver chip 03) of the driver chip 03 within the groove region B1. In this way, the heat conductive area is enlarged to further ensure reliable heat dissipation for the driver chip 03.

In some embodiments, concerning FIGS. 3 to 5, the non-display region A3 documented in the embodiments of the present disclosure includes: a first bonding region A31 and a second bonding region A32 spaced apart from each other in the second direction X, wherein the first bonding region A31 is away from the bending region A2 relative to the second bonding region A32.

The flexible printed circuit board 02 is bonded to the display panel 01 at the first bonding region A31, and the groove region B1 of the flexible printed circuit board 02 exposes the second bonding region A32. The driver chip 03 is disposed on the side, away from the display region A1, of the second bonding region A32, and is bonded to the display panel 01 at the second bonding region A32.

In some embodiments, concerning FIG. 1 and FIGS. 3 to 5, the flexible printed circuit board 02 is electrically connected to a conductive pad P1 on the side, away from the display region A1, of the first bonding region A31 by a binding member B2 (e.g., a binding adhesive) to achieve the bonded to the display panel 01.

In some embodiments, concerning FIG. 1 and FIGS. 3 to 5, the thermally conductive structure 04 is further disposed between the flexible printed circuit board 02 and the non-display region A3. That is, the thermally conductive structure 04, which is similar to a thermally conductive adhesive, fills in the gap between the flexible printed circuit board 02 and the non-display region A3 of the display panel 01. In this way, a larger heat dissipation area is further ensured, thereby achieving a better heat dissipation effect.

In some embodiments, a cross-section of the thermally conductive structure 04 in the first direction Z includes a curved edge. Further, the curved edge is concaved in a direction close to the non-display region A3; or, the curved edge protrudes in a direction away from the non-display region A3.

In some embodiments, referring to FIGS. 1, 3, and 4, the curved edge of the thermally conductive structure 04 in the first direction Z protrudes in a direction away from the non-display region A3, and accordingly, the thermally conductive structure 04 is considered as having a semi-circular cross-section. Alternatively, referring to FIG. 5, the curved edge of the thermally conductive structure 04 in the first direction Z is concaved in a direction close to the non-displayed region A3, and accordingly, the thermally conductive structure 04 is considered as having a rectangular cross-section with a concave edge. In some embodiments, the concave edge is one edge, away from the non-display region A3 (i.e., the upper side of the driver chip 03), of edges of the rectangular thermally conductive structure 04, and the concave edge is concaved in the direction close to the non-display region A3. Of course, the above is only a schematic illustration of the shape of the thermally conductive structure 04 and does not construct a limitation to the shape of the thermally conductive structure 04.

FIG. 6 is another structural schematic diagram of a display module according to some embodiments of the present disclosure. In some embodiments, referring to FIGS. 1 and 6, the display module further includes: a first back film (U-Film) 05, a bracket (BKT) layer 06, and a second back film 07 that are disposed between the display region A1 and the non-display region A3 and sequentially stacked along a first direction Z (e.g., a direction away from the display region A1.)

In some embodiments, at least one first groove K1 is defined in the bracket layer 06, wherein an orthographic projection of the at least one first groove K1 on the display panel 01 overlaps an orthographic projection of the thermally conductive structure 04 on the display panel 01. That is, in the embodiments of the present disclosure, at least one groove is formed on the bracket layer 06 in the display module.

In some embodiments, as shown in FIG. 6, a plurality of first grooves K1 (four first grooves K1 are schematically shown in FIG. 6) spaced apart from each other along the second direction X are defined in the bracket layer 06, and the plurality of first grooves K1 are disposed on the side, close to the flexible printed circuit board 02 in the first direction Z, of the bracket layer 06. Further, orthographic projections of the plurality of first grooves K1 on the display panel 01 exactly overlap the orthographic projection of the thermally conductive structure 04 on the display panel 01.

By forming the plurality of first grooves K1 as described in the above embodiments on the bracket layer 06, the contact area between the driver chip 03 and the stacked layers of the display panel 01 in the first direction Z is reduced, so as to decrease the heat dissipation in the first direction Z, which further facilitates the heat dissipation for the driver chip 03.

In some embodiments, the material of the bracket layer 06 includes: stainless steel (SUS) or metallic copper Cu. Because both the stainless steel SUS and the metallic copper Cu have better thermal conductivity, the thermal conductivity for the driver chip 03 is improved on the basis of better heat dissipation achieved by grooves.

In some embodiments, still referring to FIGS. 1 and 6, the display module further includes: a first adhesive layer 08 and a second adhesive layer 09.

In some embodiments, the first adhesive layer 08 is disposed between the first back film 05 and the bracket layer 06, and configured to adhere the first back film 05 to the bracket layer 06.

In some embodiments, the second adhesive layer 09 is disposed between the second back film 07 and the bracket layer 06, and configured to adhere the second back film 07 to the bracket layer 06.

Further, in some embodiments, a material of the first adhesive layer 08 includes a flexible material, such as polyimide (PI). In some embodiments, a material of the second adhesive layer 09 includes a non-flexible material, such as polyethylene terephthalate (PET). Accordingly, in some embodiments, the first adhesive layer 08 is also referred to as a PI adhesive, and the second adhesive layer 09 is also referred to as a PET adhesive, wherein the PET adhesive is a kind of bending tape.

On the basis of the above, as shown in FIG. 6, at least one groove is formed on the second adhesive layer 09 which has a higher strength and at a side of the bracket layer 06, so that at least one second groove K2 is defined in the second adhesive layer 09. In some embodiments, the orthographic projection of the at least one second groove K2 on the display panel 01 overlaps the orthographic projection of the thermally conductive structure 04 on the display panel 01. Of course, in some embodiments, in the case that the strength of the first adhesive layer 08 is also higher, a groove is further formed on the first adhesive layer 08. The first adhesive layer 08 is herein made of a flexible material for the purpose of protecting the display panel 01.

In some embodiments, as shown in FIG. 6, one second groove K2 is defined in the second adhesive layer 09, wherein the one second groove K2 runs through the second adhesive layer 09 in the first direction Z (accordingly, the one second groove K2 is also referred to as a through-groove), and the orthographic projection of the one second groove K2 on the display panel 01 is within the orthographic projection of the thermally conductive structure 04 on the display panel 01.

By forming the second groove K2 (i.e., the through groove) on the second adhesive layer 09 as described in the above embodiments, air circulation is accelerated, so that the heat dissipated by the driver chip 03 is carried away by the air flowing at the first groove K1, thereby reducing the concentration of heat and improving the heat dissipation speed.

Combining the above embodiments, a plurality of first grooves K1 spaced apart from each other are formed on the bracket layer 06, and at the same time, a through second groove K2 is formed on the second adhesive layer 09. In this way, under the premise of reducing the contact area of the stacked layers in the first direction Z and reducing the heat dissipation in the first direction Z, the air circulation is accelerated and the concentration of the heat is reduced, which effectively increases the speed of heat dissipation, achieves uniform heat dissipation, and avoids the display abnormality problem of yellowing of the display panel 01 at the corresponding position caused by the heat of the driver chip 03.

In some embodiments, in conjunction with another schematic diagram of film layers of a display module shown by FIG. 7, the display module further includes a thermally conductive reinforcement layer 010.

In some embodiments, the thermally conductive reinforcement layer 010 is disposed between the bracket layer 06 and at least one of the first back film 05 and the second back film 07.

In some embodiments, the thermally conductive reinforcement layer 010 shown in FIG. 7 is disposed between the bracket layer 06 and the second back film 07, and is adhered to the bracket layer 06 through the second adhesive layer 09.

In some embodiments, the material of the thermally conductive reinforcement layer 010 includes: metallic copper Cu, and accordingly, the thermally conductive reinforcement layer 010 is also referred to as a reinforcement Cu sheet. Of course, in some other embodiments, the materials of the thermally conductive reinforcement layer 010 include other metal materials, such as stainless steel SUS.

In the embodiments of the present disclosure, by disposing the reinforcement Cu sheet on a side of the bracket layer 06, the heat dissipation area in at least the second direction X is further increased, the heat dissipation efficiency is improved, and the heat dissipation for the driver chip 03 is made reliable. Of course, it is also possible to increase the heat dissipation area in the third direction Y which is located in the same plane (e.g., a plane parallel to the carrying surface of the display panel 01) as the second direction X and intersects the second direction X, so as to enable more heat to be dissipated and released along the second direction X and the third direction Y and improve the heat dissipation efficiency.

In some embodiments, still referring to FIG. 7, a groove is formed in the thermally conductive reinforcement layer 010, i.e., at least one third groove K3 is defined in the thermally conductive reinforcement layer 010, wherein an orthographic projection of the at least one third groove K3 on the display panel 01 overlap the orthographic projection of the thermally conductive structure 04 on the display panel 01.

In some embodiments, in the display module shown in FIG. 7, a plurality of third grooves K3 spaced apart from each other along the second direction X (five third grooves K3 are schematically shown in FIG. 7) are defined in the thermally conductive reinforcement layer 010, wherein the plurality of third grooves K3 are disposed at a middle position of the thermally conductive reinforcement layer 010 in the first direction Z. The middle position of the thermally conductive reinforcement layer 010 in the first direction Z means a position at a central axis of the thermally conductive reinforcement layer 010 along the second direction X. Moreover, the orthographic projections of the plurality of third grooves K3 on the display panel 01 cover the orthographic projection of the thermally conductive structure 04 on the display panel 01. Similar to the first groove K1, by forming the third groove K3 on the thermally conductive reinforcement layer 010, the contact area of the stacked layers in the first direction Z is reduced, the heat dissipation in the first direction Z is reduced, and the heat dissipation area is increased, such that the heat is evenly spread out, thereby accelerating the heat dissipation efficiency and achieving reliable heat dissipation for the driver chip 03.

It is to be noted that the above-described disposing manners regarding the first groove K1, the second groove K2, and the third groove K3 in FIGS. 6 and 7 are combined or independent of each other. In some embodiments, on the basis that one second groove K2 is defined in the second adhesive layer 09 as shown in FIG. 6, only one first groove K1 instead of four first grooves K1 spaced apart from each other is defined in the bracket layer 06 as shown in FIG. 6.

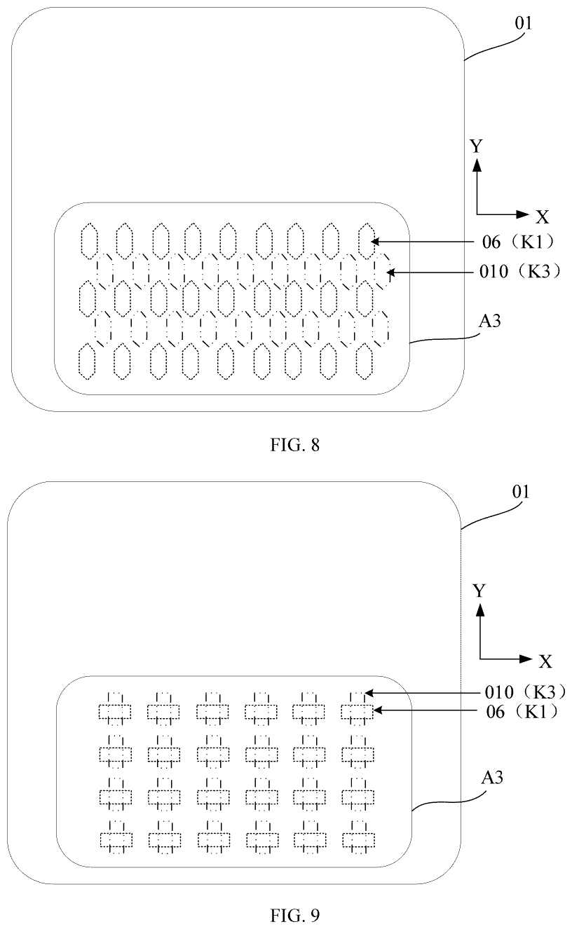

In some embodiments, as can be seen in conjunction with the plan views of the display modules respectively illustrated in FIGS. 8 to 10, the plurality of first grooves K1 (i.e., grooves on the bracket layer 06) and the plurality of third grooves K3 (i.e., grooves on the reinforcement Cu sheet 010) are arranged in any of the following patterns.

As shown in FIG. 8, the plurality of first grooves K1 and the plurality of third grooves K3 are all sequentially arranged along the second direction X and the third direction Y, and in any direction of the second direction X and the third direction Y, the orthographic projections of the plurality of first grooves K1 on the display panel 01 and the orthographic projections of the plurality of third grooves K3 on the display panel 01 are staggered.

As shown in FIG. 9, the plurality of first grooves K1 and the plurality of third grooves K3 are all sequentially arranged along the second direction X and the third direction Y, the plurality of first grooves K1 are in one-to-one correspondence with the plurality of third grooves K3, and the orthographic projection of each of the plurality of first grooves K1 on the display panel 01 is overlapped with the orthographic projection of each of the plurality of third grooves K3 on the display panel 01.

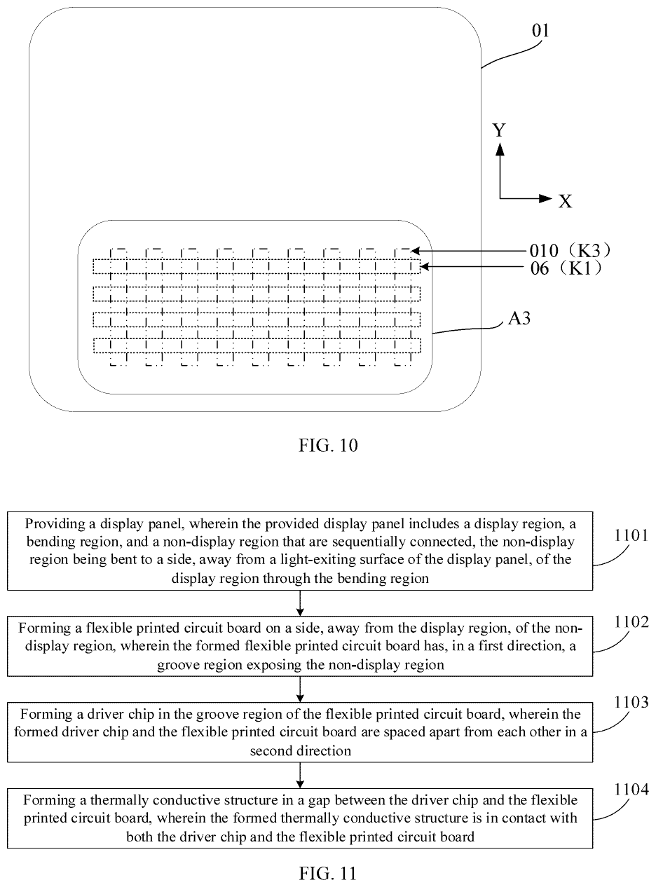

As shown in FIG. 10, the plurality of first grooves K1 are sequentially arranged along the third direction Y, the plurality of third grooves K3 are sequentially arranged along the second direction X, and the orthographic projection of each of the plurality of first grooves K1 on the display panel 01 is overlapped with the orthographic projection of each of the plurality of third grooves K3 on the display panel 01.

As described in the above embodiments, the third direction Y and the second direction X are intersected in a same plane, and each of the third direction Y and the second direction X is intersected with the first direction Z in a different plane. In some embodiments, the first direction Z is perpendicular to the carrying surface of the display panel 01, and both the second direction X and the third direction Y are parallel to the carrying surface of the display panel 01. It is noted that the above implementations shown in FIGS. 8 to 10 are only schematic illustrations of the groove arrangement.

In some embodiments, referring to FIG. 8, the orthographic projection of any of the first groove K1, the second groove K2, and the third groove K3 on the display panel 01 has a shape of a hexagon. In some embodiments, the display panel 01 further includes a plurality of pixels, wherein an orthographic projection of any of the pixels on the display panel 01 has a shape of a hexagon, which herein generally refers to an anode shape. On the basis of the above, in some embodiments, the above-described arrangement of grooves in hexagonal shapes refers to the arrangement of the plurality of pixels. Accordingly, in some embodiments, the grooves shown in FIG. 8 are also referred to as pixel-type grooves. In some embodiments, on the basis of disposing the grooves by referring to the arrangement of the plurality of pixels, the grooves are formed by etching by further referring to the forming process of the pixels, thereby simplifying the process, saving the manufacturing cost, and speeding up the manufacturing efficiency.

Alternatively, in some embodiments, as can be seen in conjunction with FIGS. 9 and 10, the orthographic projection of any of the first groove K1, the second groove K2, and the third groove K3 on the display panel 01 has a shape of a rectangle. Moreover, referring to the structure shown in FIG. 9, the rectangular grooves are also referred to as square-shaped grooves. Referring to the arrangement shown in FIG. 10, the rectangular grooves are also referred to as through-hole-shaped grooves. Of course, the above shapes are only illustratively described, and the grooves have other shapes, such as round, oval, or triangular.

In some embodiments, as for any of the first groove K1 (which is also referred to as a first type of groove), the second groove K2 (which is also referred to as a second type of groove), and the third groove K3 (which is also referred to as a third type of groove), there are several implementation manners as described below.

First, in conjunction with FIGS. 8 to 10, the plurality of grooves of a same type have a same shape. In some embodiments, referring to FIG. 8, the plurality of first grooves K1 have the same shape, all being hexagonal. Of course, in some other embodiments, the plurality of grooves of a same type have different shapes. In some embodiments, a portion of the plurality of first grooves K1 is rectangular, and another portion of the plurality of first grooves K1 is hexagonal. Second, the grooves of different types have a same shape. In some embodiments, referring to FIG. 8, the first grooves K1 and the third grooves K3 have the same shape, both being hexagonal. Of course, in some other embodiments, the grooves of different types have different shapes. In some embodiments, the first groove K1 is rectangular and the third groove K3 is hexagonal.

Third, every two adjacent grooves of the plurality of grooves of a same type have a fixed spacing, i.e., the spacing between any two adjacent grooves is fixed. Of course, in some other embodiments, the spacing between any two adjacent grooves is unfixed.

Fourth, the sizes of the grooves of the same type are the same. In some embodiments, the size herein is a cross-sectional area of the groove in a direction perpendicular to a carrying surface of the display panel 01. Of course, in some other embodiments, the sizes of the grooves of the same type are different.

In some embodiments, the first groove K1, the second groove K2, and the third groove K3 described in the above embodiments are formed by an etching process, and therefore also referred to as etched grooves.

In some embodiments, referring to FIG. 1, the display module provided by the embodiments of the present disclosure further includes a connecting portion B0 disposed between the flexible printed circuit board 02 and the non-display region A3 of the display panel 01. The connecting portion B0 is configured to reliably fix the flexible printed circuit board 02 to the display panel 01, thereby enhancing the connection strength between the flexible printed circuit board 02 and the display panel 01 and avoiding tearing phenomena. In some embodiments, the connection portion B0 herein is a pressure-sensitive adhesive (PSA), a double-sided adhesive, or a thermally conductive copper foil.

In some embodiments, referring to FIGS. 6 and 7, the display module provided by the embodiments of the present disclosure further includes: a double-sided adhesive JI overlaid on a surface, away from the display region A1 and the non-displayed region A3, of the bending region A2 of the display panel 01. The double-sided adhesive JI is configured to protect the bending region A2 (e.g., protecting the metal traces within the bending region A2.)

In some embodiments, referring to FIGS. 1, 6, and 7, the display module provided by the embodiments of the present disclosure further includes: a device region Q1 disposed on a side, away from the non-display region A3, of the flexible printed circuit board 02. In some embodiments, the device region Q1 includes electronic components such as capacitors, resistors, and/or flash memory. In some embodiments, referring to FIGS. 6 and 7, the display module further includes: other modules MO, such as a power supply battery, disposed on a side, away from the display region A1, of the bracket layer 06.

Based on the above description, the bonding scheme used in the display module provided by the embodiments of the present disclosure is also referred to as an FPC reverse bonding IC scheme, which effectively conducts and exports the heat of the IC, improves the reliability of the display module, reduces the heat dissipation in the first direction Z, increases the heat conductivity in the second direction X and the third direction Y, improves the heat dissipation efficiency, achieves the purpose of uniform heat dissipation, and solves the display yellowing problem of the display panel. In addition, the solution provided by the embodiments of the present disclosure is applicable to various types of FPC IC aperture structures, and the design of etching grooves for foldable products improves the heat dissipation efficiency and at the same time reduces the weight of the product.

In summary, the embodiments of the present disclosure provide a display module. In the display module, a flexible printed circuit board disposed in a non-display region, that is bent to a side, away from the light-exiting surface, of the display region through a bending region, has a groove region that exposes the non-display region. The driver chip is disposed in the groove region and is spaced apart from the flexible printed circuit board. In addition, the gap between the driver chip and the flexible printed circuit board is filled with a thermally conductive structure. In this way, better heat dissipation for the driver chip is achieved, and the problem of abnormal pixel brightness at the position corresponding to the driver chip caused by the heat of the driver chip upon working for a long time is avoided. That is, the display abnormality problem similar to yellowing of the display panel in the display module is avoided, i.e., a good display effect of the display panel is ensured.

FIG. 11 is a flowchart of a method for manufacturing a display module according to some embodiments of the present disclosure. The method is applicable for manufacturing the display module provided by the above embodiments. As shown in FIG. 11, the method includes the following processes.

In process 1101, a display panel is provided, wherein the provided display panel includes a display region, a bending region, and a non-display region that are sequentially connected, the non-display region being bent to a side, away from a light-exiting surface of the display panel, of the display region through the bending region.

In process 1102, a flexible printed circuit board is formed on a side, away from the display region, of the non-display region, wherein the formed flexible printed circuit board has, in a first direction, a groove region exposing the non-display region.

In process 1103, a driver chip is formed within the groove region of the flexible printed circuit board, wherein the formed driver chip and the flexible printed circuit board are spaced apart from each other in the second direction.

In some embodiments, the second direction X intersects the first direction Z (e.g., perpendicular to each other) as shown in FIG. 1.

In process 1104, a thermally conductive structure is formed within a gap between the driver chip and the flexible printed circuit board, wherein the formed thermally conductive structure is in contact with both the driver chip and the flexible printed circuit board.

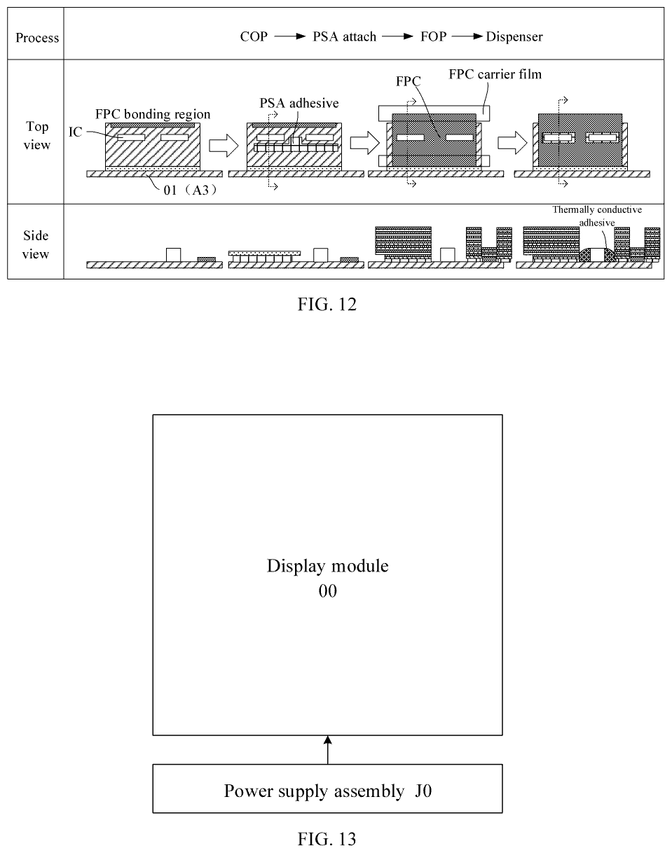

In some embodiments, taking the structure shown in FIG. 1 as an example, FIG. 12 shows a flowchart of a manufacturing process. As shown in FIG. 12, firstly, a COP process is performed on a substrate, i.e., the IC and the flexible printed circuit board FPC are disposed and bonded onto the non-display region A3 of the display panel 01. FIG. 12 illustratively shows two ICs. Then, the attachment of a pressure-sensitive adhesive is performed, i.e., a PSA attach process. Subsequently, the FOP process is performed in the non-display region A3, i.e., the FPC carrier film is disposed in the non-display region. At this time, the disposing of the FPC and the IC is completed. Moreover, in the embodiments of the present disclosure, the FPC includes a groove region B1, and the bonded IC is disposed in the groove region B1. Finally, a thermally conductive structure 04 (e.g., a thermally conductive adhesive) described in the above embodiments fills in the groove region B1, which is also referred to as a dispenser. Specifically, the thermally conductive structure 04 fills in the gap between the IC and the FPC, to achieve thermal conduction.

It should be noted that, in some embodiments, the grooves or holes in the embodiments of the present disclosure are formed through an etching process as described in the above embodiments, and some different film layers are processed and etched through one process to avoid an increase in cost.

In summary, the embodiments of the present disclosure provide a method for manufacturing a display module. In the display module manufactured by the method, a flexible printed circuit board disposed in a non-display region, that is bent to a side, away from the light-exiting surface, of the display region through a bending region, has a groove region that exposes the non-display region. The driver chip is disposed in the groove region and is spaced apart from the flexible printed circuit board. In addition, the gap between the driver chip and the flexible printed circuit board is filled with a thermally conductive structure. In this way, better heat dissipation for the driver chip is achieved, and the problem of abnormal pixel brightness at the position corresponding to the driver chip caused by the heat of the driver chip upon working for a long time is avoided. That is, the display abnormality problem similar to yellowing of the display panel in the display module is avoided, i.e., a good display effect of the display panel is ensured.

In some embodiments, another display module is provided. Referring to FIG. 1, the display module includes:
a display panel 01, including a display region A1, a bending region A2, and a non-display region A3 that are sequentially connected, wherein the non-display region A3 is bent to a side, away from the light-exiting surface of the display panel 01, of the display region A1 through the bending region A2;
a flexible printed circuit board 02, disposed on a side, away from the display region A1, of the non-display region A3, bonded to the non-display region A3, and having, in a first direction Z, a groove region B1 exposing the non-display region A3;
a driver chip 03, disposed within the groove region B1 of the flexible printed circuit board 02 and bonded to the non-display region A3, wherein in a second direction X, any side wall of the driver chip 03 is spaced apart from any side wall of the flexible printed circuit board 02, the second direction X being intersected with the first direction Y; and
a thermally conductive structure 04, disposed within a gap between the driver chip 03 and the flexible printed circuit board 02 and being in contact with each of the driver chip 03, the flexible printed circuit board 02, and the non-display region A3.

FIG. 13 is a structural schematic diagram of a display device according to some embodiments of the present disclosure. As shown in FIG. 13, the display device includes: a power supply assembly JO, and a display module 00 as described in the above embodiments.

In some embodiments, the power supply assembly JO is coupled to the display module 00 and configured to supply power to the display module 00.

In some embodiments, the display module 00 is a foldable display module as described in the above embodiments. In some embodiment, the display device is a cell phone, a tablet computer, a flexible display device, a television set, a monitor, or any other product or component having a display function.

It should be understood that the terms used in the embodiments of the present disclosure are used for the purpose of explaining the embodiments of the present disclosure and are not intended to limit the present disclosure. Unless otherwise defined, technical or scientific terms used in the embodiments of the present disclosure should have the ordinary meaning understood by a person of ordinary skill in the art to which the present disclosure belongs.

In the description and the claims of the present disclosure, the terms “first,” “second,” “third,” or the like are used for distinguishing different components only and are not to be construed as indicating or implying any sequence, number, or relative importance.

Similarly, similar terms such as “one” or “a” do not indicate a quantitative limitation, but indicate the existence of at least one object.

Similar terms such as “include” or “comprise” mean that the element or object appearing before “include” or “comprise” covers the element, object, or their equivalents appearing behind “include” or “comprise”, but do not exclude other elements or objects.

The terms “up,” “down,” “left,” or “right” are used only to indicate relative positional relationships, and in the case that the absolute position of the described object is changed, the relative positional relationship is also possible to change accordingly. The terms such as “connect to” or “coupled to” are electrical connections.

The phrase “and/or” means that three relationships are included. For instance, A and/or B include three cases: only A, both A and B, and only B. The character “/” generally means that the objects appearing before and behind the character have an “or” relationship.

The foregoing are only optional embodiments of the present disclosure, and are not intended to limit the present disclosure, and any modifications, equivalent substitutions, improvements, etc. made within the concept and principles of the present disclosure shall be included in the scope of protection of the present disclosure.

1. A display module, comprising:
a display panel, comprising a display region, a bending region, and a non-display region that are sequentially connected, wherein the non-display region is bent to a side, away from a light-exiting surface of the display panel, of the display region through the bending region;
a flexible printed circuit board, disposed on a side, away from the display region, of the non-display region and having, in a first direction, a groove region exposing the non-display region;
a driver chip, disposed on the side, away from the display region, of the non-display region and within the groove region of the flexible printed circuit board and spaced apart from the flexible printed circuit board in a second direction, the second direction being intersected with the first direction; and
a thermally conductive structure, disposed within a gap between the driver chip and the flexible printed circuit board and being in contact with both the driver chip and the flexible printed circuit board.

2. The display module according to claim 1, wherein the thermally conductive structure comprises a thermally conductive adhesive.

3. The display module according to claim 1, wherein an orthographic projection of the thermally conductive structure on the display panel covers an orthographic projection of the driver chip on the display panel.

4. The display module according to claim 1, wherein the non-display region comprises a first bonding region and a second bonding region spaced apart from each other in the second direction, the first bonding region being away from the bending region relative to the second bonding region; wherein
the flexible printed circuit board is bonded to the display panel at the first bonding region and the second bonding region is exposed by the grove region of the flexible printed circuit board; and
the driver chip is disposed on a side, away from the display region, of the second bonding region and is bonded to the display panel at the second bonding region.

5. The display module according to claim 1, wherein the thermally conductive structure is further disposed between the flexible printed circuit board and the non-display region.

6. The display module according to claim 1, wherein a cross-section of the thermally conductive structure in the first direction has a curved edge.

7. The display module according to claim 1, further comprising:
a first back film, a bracket layer, and a second back film that are disposed between the display region and the non-display region and sequentially stacked along the first direction;
wherein at least one first groove is defined in the bracket layer, an orthographic projection of the at least one first groove on the display panel being overlapped with an orthographic projection of the thermally conductive structure on the display panel.

8. The display module according to claim 7, further comprising:
a first adhesive layer, disposed between the first back film and the bracket layer and configured to adhere the first back film to the bracket layer; and
a second adhesive layer, disposed between the second back film and the bracket layer and configured to adhere the second back film to the bracket layer; wherein
a material of the first adhesive layer comprises a flexible material and a material of the second adhesive layer comprises a non-flexible material; and
at least one second groove is defined in the second adhesive layer, an orthographic projection of the at least one second groove on the display panel being overlapped with the orthographic projection of the thermally conductive structure on the display panel.

9. The display module according to claim 8, further comprising:
a thermally conductive reinforcement layer, disposed between the bracket layer and at least one of the first back film and the second back film.

10. The display module according to claim 9, wherein
the thermally conductive reinforcement layer is disposed between the bracket layer and the second back film and adhered to the bracket layer via the second adhesive layer; and
at least one third groove is defined in the thermally conductive reinforcement layer, an orthographic projection of the at least one third groove on the display panel being overlapped with the orthographic projection of the thermally conductive structure on the display panel.

11. The display module according to claim 10, wherein a plurality of first grooves spaced apart from each other along the second direction are defined in the bracket layer, the plurality of first grooves being disposed on a side, close to the flexible printed circuit board in the first direction, of the bracket layer, and orthographic projections of the plurality of first grooves on the display panel being overlapped with the orthographic projection of the thermally conductive structure on the display panel;
and/or,
one second groove is defined in the second adhesive layer, the one second groove running through the second adhesive layer in the first direction, and an orthographic projection of the one second groove on the display panel being within the orthographic projection of the thermally conductive structure on the display panel;
and/or,
a plurality of third grooves spaced apart from each other along the second direction are defined in the thermally conductive reinforcement layer, the plurality of third grooves being disposed at a middle position of the thermally conductive reinforcement layer in the first direction, and the orthographic projections of the plurality of third grooves on the display panel being overlapped with the orthographic projection of the thermally conductive structure on the display panel.

12. The display module according to claim 10, wherein a plurality of first grooves are defined in the bracket layer and a plurality of third grooves are defined in the thermally conductive reinforcement layer; wherein the plurality of first grooves and the plurality of third grooves are arranged in any of the following patterns:
the plurality of first grooves and the plurality of third grooves are all sequentially arranged along the second direction and a third direction, and in any direction of the second direction and the third direction, orthographic projections of the plurality of first grooves on the display panel and orthographic projections of the plurality of third grooves on the display panel are staggered;
the plurality of first grooves and the plurality of third grooves are all sequentially arranged along the second direction and the third direction, the plurality of first grooves are in one-to-one correspondence with the plurality of third grooves, and the orthographic projection of each of the plurality of first grooves on the display panel is overlapped with the orthographic projection of each of the plurality of third grooves on the display panel; or
the plurality of first grooves are sequentially arranged along the third direction, the plurality of third grooves are sequentially arranged along the second direction, and the orthographic projection of each of the plurality of first grooves on the display panel is overlapped with the orthographic projection of each of the plurality of third grooves on the display panel;
wherein the third direction and the second direction are intersected in a same plane, and the third direction and the second direction are intersected with the first direction respectively in different planes.

13. The display module according to claim 10, wherein the orthographic projection of any one of the first groove, the second groove, and the third groove on the display panel has a shape of a hexagon or rectangle.

14. The display module according to claim 9, wherein the material of the first adhesive layer comprises polyimide; a material of the bracket layer comprises stainless steel or metallic copper; the material of the second adhesive layer comprises polyethylene terephthalate; and a material of the thermally conductive reinforcement layer comprises metallic copper.

15. The display module according to claim 1, wherein the flexible printed circuit board comprises:
a plurality of protective layers and a plurality of metal trace layers that are alternately stacked along the first direction, wherein a material of the metal trace layer comprises metallic copper.

16. The display module according to claim 1, wherein the display module further comprises:
a connection portion, disposed between the flexible printed circuit board and the non-display region and configured to connect the flexible printed circuit board to the display panel.

17. The display module according to claim 1, further comprising:
a double-sided adhesive, overlaid on a surface, away from the display region and the non-display region, of the bending region and configured to protect the bending region.

18. A method for manufacturing a display module, applicable to manufacturing the display module as defined in claim 1, the method comprising:
providing a display panel, wherein the display panel comprises a display region, a bending region, and a non-display region that are sequentially connected, the non-display region being bent to a side, away from a light-exiting surface of the display panel, of the display region through the bending region;
forming a flexible printed circuit board on a side, away from the display region, of the non-display region, wherein the formed flexible printed circuit board has, in a first direction, a groove region exposing the non-display region;
forming a driver chip in the groove region of the flexible printed circuit board, wherein the formed driver chip and the flexible printed circuit board are spaced apart from each other in a second direction, the second direction being intersected with the first direction; and
forming a thermally conductive structure in a gap between the driver chip and the flexible printed circuit board, wherein the formed thermally conductive structure is in contact with both the driver chip and the flexible printed circuit board.

19. A display module, comprising:
a display panel, comprising a display region, a bending region, and a non-display region that are sequentially connected, wherein the non-display region is bent to a side, away from a light-exiting surface of the display panel, of the display region through the bending region;
a flexible printed circuit board, disposed on a side, away from the display region, of the non-display region, bonded to the non-display region, and having, in a first direction, a groove region exposing the non-display region;
a driver chip, disposed within the groove region of the flexible printed circuit board and bonded to the non-display region, wherein in a second direction, any side wall of the driver chip is spaced apart from any side wall of the flexible printed circuit board, the second direction being intersected with the first direction; and
a thermally conductive structure, disposed within a gap between the driver chip and the flexible printed circuit board and being in contact with each of the driver chip, the flexible printed circuit board, and the non-display region.

20. A display device, comprising: a power supply assembly, and a display module;
wherein the power supply assembly is coupled to the display module and configured to supply power to the display module; and
the display module comprises:
a display panel, comprising a display region, a bending region, and a non-display region that are sequentially connected, wherein the non-display region is bent to a side, away from a light-exiting surface of the display panel, of the display region through the bending region;
a flexible printed circuit board, disposed on a side, away from the display region, of the non-display region and having, in a first direction, a groove region exposing the non-display region;
a driver chip, disposed on the side, away from the display region, of the non-display region and within the groove region of the flexible printed circuit board and spaced apart from the flexible printed circuit board in a second direction, the second direction being intersected with the first direction; and
a thermally conductive structure, disposed within a gap between the driver chip and the flexible printed circuit board and being in contact with both the driver chip and the flexible printed circuit board.
